(19) United States
(12) Patent Application Publication
(10) Pub. No.: US 2004/0008489 A1
(43) Pub. Date: Jan. 15, 2004

(54) Electronic device

(76) Inventors: Rintaro Minamitani, Tsuchiura (JP); Takashi Naganawa, Tsuchiura (JP); Makoto Kitano, Tsuchiura (JP); Yuuji Yoshitomi, Tsuchiura (JP); Yoshihiro Kondo, Tsuchiura (JP); Shigeo Ohashi, Tsuchiura (JP); Hajime Katou, Tsuchiura (JP); Masato Nakanishi, Tsuchiura (JP); Tsuyoshi Nakagawa, Ebina (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/239,140

(22) PCT Filed: Jul. 10, 2002
(86) PCT No.: PCT/JP02/07009

(51) Int. Cl. H05K 7/20

(52) U.S. Cl. 361/699

(57) ABSTRACT

An electronic equipment or apparatus, small-sized and thinned in the thickness thereof, having a system for cooling an semiconductor element generating high temperature, comprising: a case mounting the semiconductor element within an inside thereof; a heat-receiving member being thermally connected with the semiconductor element; a heat-radiation member being disposed on an interior surface side of the case; a liquid driving means for driving a liquid coolant between the heat-radiation member and the heat-receiving member; a tank for accumulating the liquid coolant therein; and tubes for connecting between the tank, the heat-radiation member, and the heat-receiving member, wherein the tube is made of either one of butyl rubber, nitrobutadien rubber, fluororubber, ethylene-propylene rubber, hydrinrubber, or polysulfide rubber, so that a permeation amount “q” of the coolant is determined to be equal to or less than a containing amount “Q” of the coolant. Also, a protection tape or a protection tube is attached on a curved portion of the tube, for use of protection from abrasion and buckling, and the tube is formed, by winding itself in advance, fitting to a shape of a curved portion thereof.

### TECHNICAL FIELD

The present invention relates to an electronic apparatus, in which a semiconductor elements generating heat therefrom is cooled by a liquid circulating therein.

### BACKGROUND ART

Conventionally, as a means for cooling a semiconductor element in an electronic apparatuses, in addition to cooling due to the natural convection, and/or compulsive cooling by means of a fan, etc., there are already known one by using a heat-pipe and one through water-cooling, etc.

An electronic equipment or apparatus equipped with such the heat-pipe, relating to the conventional art, is already known, for example, in Japanese Patent Laying-Open No. Hei 1-84699 (1989), and Japanese Patent Laying-Open No. Hei 2-244748 (1990).

Cooling by means of a water-cooling device, being equipped with such the heat-pipe, is superior in efficiency, since it does not use a part consuming electricity, such as an air-blower, and it can further increase the efficiency of cooling due to hear or thermal conductivity.

A cooling device applying the water-cooling, relating to the conventional arts, is already known, for example, in Japanese Patent Laying-Open No. Hei 5-335454 (1993) or Japanese Patent Laying-Open No. Hei 6-125188 (1994).

Further, a small-sized personal computer having the cooling device applying the water-cooling, in relation to the conventional arts, is also already known, for example, in Japanese Patent Laying-Open No. Hei 6-266474 (1994) or Japanese Patent Laying-Open No. Hei 7-142886 (1995).

Among of them, in particular in the Japanese Patent Laying-Open No. Hei 6-266474 (1994) is disclosed the structure of a notebook-type personal computer, mounting a heat-generating element therein, and further comprising a main housing or case, on which a keyboard is provided, and a housing or case of display side, which includes a display panel and is attached to the main case rotatably, and wherein onto the heat-generating element is attached a heat-receiving jacket, while a heat-radiation pipe and a pump provided within the case of the display device are connected with each other through connection tubes.

Further, in Japanese Patent Laying-Open No. Hei 7-142886 (1995) or Japanese Patent Laying-Open No. Hei 6-266474 (1994) is disclosed an example, in which the cases are made of a metal.

By the way, with the notebook-type personal computer mentioned above, in general, the display case having the heat-radiation pipe therein can be always opened and closed with respect to the main case having the heat-receiving jacket therein, in the structure thereof, therefore they must be connected by means of a flexible tube, in any means, in a hinge portion thereof.

With personal computers, such as the notebook-type, as well as, a desktop-type and a server, in recent years, any one is small-sized and pipes for use of water-cooling must be drawn around within the electronic apparatus, therefore it is preferable to adopt a flexible tube.

However, the flexible tube has a drawback that the water within the tube penetrates or permeates therethrough, but no consideration was paid upon a material, through which the water cannot come out, in any one of the conventional arts mentioned above.

Thus, when using the flexible tube having a large water permeation therethrough, an amount of water contained is reduced, and thereby bringing about a problem that cooling cannot be achieved on the heat-generating element.

Also, in the hinge portion of the display case, being rotatably movable with respect to the main case, application of a load due to repetition of open/close of the display case results in frictional wear or abrasion on the flexible tube, and therefore there occurs a problem that the water comes out from the abrasion portion.

And also, within the cases, the flexible tubes are drawn round under the condition of small curvature radius, and in particular in the case where they are kept under such the shapes for a long time, the flexible tube is compressed or buckled in a part, so that it chokes a flow passage, thereby bringing about a problem that cooling cannot be performed fully, upon the heat-generating element due to decrease of the flow amount.

### DISCLOSURE OF THE INVENTION

An object is, therefore, according to the present invention, to provide an electronic equipment or apparatus, being able to reduce an amount of permeation of a coolant from the connection tubes, to prohibit the leakage of coolant due to abrasion of the flexible tube, and/or to prevent the flow amount from being decreased due to the buckle of the flexible tube, thereby enabling cooling of the semiconductor element with stability for a long time.

The object mentioned above, according to the present invention, can be achieved by an electronic equipment or apparatus, comprising: a case mounting a semiconductor element within an inside thereof; a heat-receiving member being thermally connected with said semiconductor element; a heat-radiation member being disposed on an interior surface side of said case; a liquid driving means for driving a liquid coolant between said heat-radiation member and said heat-receiving member; a tank for accumulating said liquid coolant therein; and tubes for connecting between the tank, said heat-radiation member, and said heat-receiving member, wherein at least a part of said tube is made of butyl rubber.

Also, the object mentioned above, according to the present invention, can be achieved by the electronic equipment or apparatus, as described in the above, wherein at least a part of said tube is formed of either one of nitrobutadien rubber, fluororubber, ethylene-propylene rubber, hydrinrubber, and polysulfide rubber.

Also, the object mentioned above, according to the present invention, can be achieved by the electronic equipment or apparatus, as described in the above, wherein a penetration amount “q” of the coolant, which can be expressed by the equation (2) blow, is determined to be equal to or less than a containing amount “Q” of the coolant.

Also, the object mentioned above, according to the present invention, can be achieved by the electronic equipment or apparatus, as described in the above, wherein a protection tape is attached on a curved portion of said tube, for use of protection from abrasion and buckling.

Also, the object mentioned above, according to the present invention, can be achieved by the electronic equipment or apparatus, as described in the above, wherein a protection tube is attached on an outer periphery of a curved portion of said tube, for use of protection from abrasion and buckling, and said protection tube has an inner diameter being larger than an outer diameter of said connection tube.

And, the object mentioned above, according to the present invention, can be achieved by the electronic equipment or apparatus, as described in the above, wherein said tube is formed, by winding itself in advance, fitting to a shape of a curved portion thereof.

### BRIEF DESCRIPTION OF THE DRAWINGS

FIG. 1 is a perspective view of a notebook-type personal computer, applying a cooling system therein, according to a first embodiment of the present invention;

FIG. 2 is a perspective view of a notebook-type personal computer, applying a cooling system therein, according to a second embodiment of the present invention;

FIG. 3 is a partial enlarged view for showing a connector tube, passing by between a main case and a display case of an electronic equipment or apparatus, according to a third embodiment of the present invention;

FIG. 4 is a perspective view for showing the details of a hinge portion between the main case and the display case, in the structure of the electronic equipment or apparatus, according to the embodiment mentioned above;

FIGS. 5(a) and 5(b) are partial enlarged views, for showing the conditions of a connector tube mentioned above, before the use and after a long-term use thereof;

FIG. 6 is a view for showing the structure, in which a protection tube is attached on the tube, but in a portion other than the hinge portion between the main case and the display case, in the embodiment mentioned above;

FIGS. 7(a) and 7(b) are views for showing the conditions of the connector tube, passing by between the main case and the display case, in the electronic equipment or apparatus, according to a fourth embodiment of the present invention; and

FIG. 8 is a partial enlarged view, for showing the condition that a protection tube is attached onto the tube in a portion other than the hinge portion between the main case and the display case, in the electronic equipment or apparatus, according to a fifth embodiment of the present invention.

### BEST MODE FOR CARRYING OUT THE INVENTION

An electronic equipment or apparatus, such as a so-called personal computer, includes a notebook-type personal computer, which is portable, and a desktop-type personal computer, which is mainly used on a desk.

In each of those personal computers, being demanded to be higher and larger in processing speed and capacity thereof every year, temperature of the heat generation of a CPU, i.e., the semiconductor element, comes up to be higher, as a result of those requirements. And it is expected that this tendency will continue further in future.

On the contrary to this, in general, the personal computers are mainly of an air-cooling type by means of a fan or the like, or a heat or thermo-conductive type, at the present situation. Those cooling method have a limit in the capacity of heat-radiation, and there is a possibility that they cannot follow the heat-radiation of the CUP, which is on such the tendency of high heat-generation, as was mentioned above. However, it may be possible to treat with this, by making the fan rotating at higher speed and/or larger in the size thereof, however it brings about an effect against requirements for the personal computer, such as low-noise generation and/or light-weighting, therefore it is not a realistic solution.

On the other hand, as a method for heat-radiation, to be replaced with heat-radiation of the conventional air-cooling type, there is an apparatus adopting a device for cooling the CPU, by circulating a cooling medium or coolant, such as water, etc.

Such the cooling device is mainly used in a cooling system for a large-scaled computer, being located in a company or bank, etc., and wherein cooling water is circulated compulsively by means of a pump, and is cooled by a refrigerator for exclusive use thereof, thereby being large in the scale or sizes thereof.

Accordingly, such the cooling device by means of water as was mentioned above is unable, at all, to be mounted into the notebook-type personal computer, which may be moved or carried with frequently, and into the desk-top personal computer, which also may be moved due to, such as re-arrangement in an office, etc., even if this cooling device can be made small in the sizes, for example.

Then, as was in the conventional arts mentioned above, various devices are studied, for achieving the cooling through water, which can be mounted on a small-sized personal computer, however the temperature of heat-generation by the semiconductor element was not so high as in the recent year, at the time when such the conventional arts were made and filed as the patent applications, therefore no personal computer equipped with the water-cooling device comes out available on markets as an actual product, until up to now.

On the contrary to this, according to the present invention, small-sizing of the water-cooling device can be achieved, drastically, by building up the case defining an external form of the main body of a computer, from aluminum alloy or magnesium alloy, etc., being superior in heat-radiation, thereby enabling the water-cooling device to be amounted onto the personal computer.

However, it could be found by the present inventors that there is still a new problem when trying to mount such the water-cooling device. In particular, with the notebook-type personal computer, in relation to the fact that the display thereof is folded very frequently, in the actual use thereof, there is a minimal condition that the pipes must be made from a flexible tube in the hinge portion connecting between the heat-receiving portion and the heat-radiation pipe portion. As a result of conducting various studies upon an actual model with using this flexible tube therein, it can be found that a problem occurs; i.e., the water within the tube permeates or comes out through the surface of the tube and evaporates enters into an outside thereof, thereby decreasing an amount of the water therein.

Then, according to the present invention, studies are made on the flexible tubes made of materials, for suppressing in the permeation of water from the tube, and as a result can be found specific materials having a small water penetration in the property.

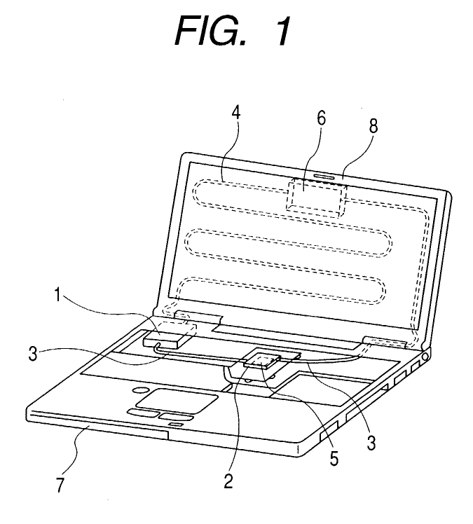

Hereinafter, explanation will be given on a first embodiment according to the present invention, by referring to FIG. 1 attached.

FIG. 1 is a perspective view for showing a notebook-type personal computer equipped with a cooling system, according to the first embodiment of the present invention.

In the figure, with a semiconductor element 5 mounted within a case 7 of a main body of the personal computer is connected a heat-receiving jacket 2, within which a flow passage is provided for a coolant liquid. To this heat-receiving jacket 2 is connected a pump 1. On a rear surface of a display panel in a display case 2 are provided a tank 6 and a heat radiation pipe 4. The pump 1, the heat-radiation jacket 2, the tank 6 and the heat-radiation pipe 4 are connected in loop-like through connection tubes 3, as shown in the figure, and within an inside thereof is filled up with the coolant, such as the water, etc. Those tubes 3 are, preferably, made of an organic material tube, from a viewpoint that the degrees of freedom can be increased in a layout, including the pump 1, the heat-receiving jacket 2, the tank 6 and the heat-radiation pipe 4, and that a connection hinge portion A is rotated, repetitively, up to 180 degree.

Also, by taking the volume within the cases of the notebook-type personal computer and/or the desktop-type personal computer into the consideration, it could be found that, preferably, the water contained therein is from 100 cc to 500 cc in the minimal amount thereof, necessary for cooling of the CPU.

By the way, the organic material tube building up the connection tubes 3 can permeates the coolant through it, such as the water and/or an anti-freezing, etc., and then, upon operation for a long time, lowering occurs in the amount of the water contained therein, therefore the semiconductor element 5 cannot be cooled down, fully.

It could be found that, if using a silicon tube (having an outer diameter of 5 mm, an inner diameter 3 mm, and a length of 300 mm) under the condition of the water (or the coolant) of 70° C., for example, in five (5) years thereafter, the water of 1,550 cc permeates therethrough. Also, the rate of permeability of the water for the silicon rubber is 730×10⁻⁶ g/mm²/24 h/(atm/mm). Namely, it means that the total of the contained water can permeate or comes out through.

Then, according to the present invention, a tube made of butyl rubber is adopted as the connection tube, which has the chemical constitution or structure expressed by the following chemical formula (1).

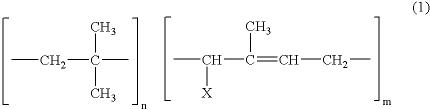

The butyl rubber, in this case, shows a feature of being small in the rate of permeability thereof, and being superior in tolerance or resistance (an anti-solubility) against an agent, such as the water and the anti-freezing fluid.

It could be found that, when using the butyl rubber tube (having an outer diameter of 5 mm, an inner diameter 3 mm, and a length of 300 mm) under the condition of the water (or the coolant) of 70° C., for example, in five (5) years thereafter, only the water of 4.4 cc can permeates therethrough. The rate of permeability of the butyl rubber for the water is 2.1×10⁻⁶ g/mm²/24 h/(atm/mm).Also, in the place of the butyl rubber may be used nitrilbutadien rubber, fluororubber, ethylene-propylene rubber, hydrinrubber, or polysulfide rubber, each being small in the liquid permeability in the same manner.

From other viewpoint, i.e., in order to ensure reliability of the cooling system for the term of guarantee, it is required that the liquid permeability of the connector tube is equal to or less than the holding or containing amount of the coolant, in other words that an amount of permeability for coolant “q” of the connector tube, which can be expressed by the following equation (2), is equal to or less than the containing amount “Q” of the coolant:

q=2π.P.L.Δp.t/(In(r2/r1)) (2)

where “P” represents the rate of permeability of the coolant at the maximum temperature in use, “L” the total length of the connector tube, “Δp” the pressure difference between an inside and an outside of the tube (i.e. the vapor pressure difference) at the maximum temperature in use, “t” the longest time-period of use, “r1” the inner diameter of the tube, and “r2” the outer diameter of the tube, respectively. In a case where it is impossible to satisfy the condition that the amount of the liquid permeability is equal to or less than the containing amount of coolant, it is necessary to supply the coolant within the warranty period.

By the way, the butyl rubber is applied to, in general, the pipe for use in connection of a radiator in an automobile, or the tube of a tire, and is known that it is superior in the heat-resistance and the property of anti-permeability.

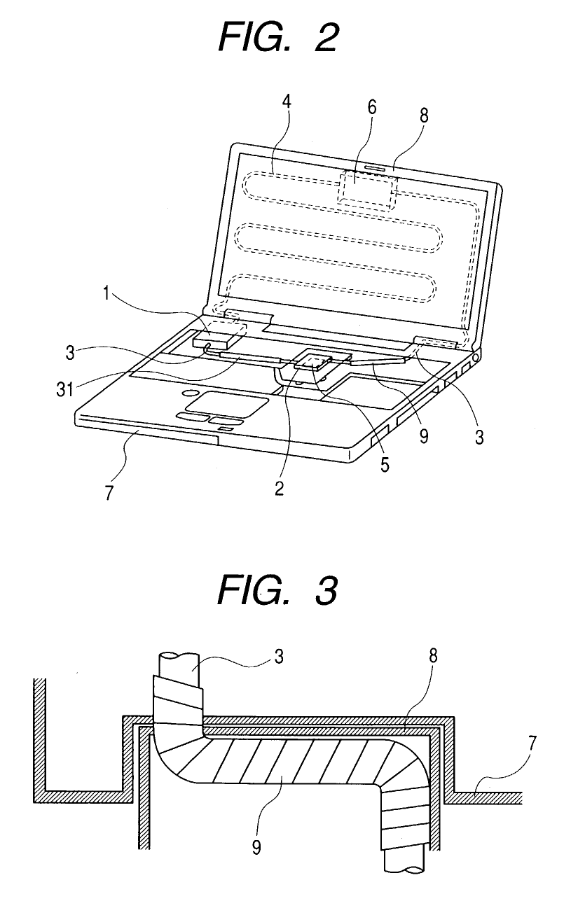

FIG. 2 is a perspective view for showing a notebook-type personal computer, according to a second embodiment of the present invention.

In FIG. 2, connector tubes 3, connecting among a pump 1, a heat-receiving jacket 2, a tank 6 and a heat-radiation pipe 4, are made from an organic material tube 31 and a metal pipe 32. As the metal pipe 32 can be listed up one made of stainless or copper.

With provision of the metal pipe 32, it is possible to shorten the length of the organic tube 31 for a portion of the metal pipe 32 having zero (0) in the liquid permeability, and as a result thereof, it is possible to lower an amount of the liquid permeating through the connector tube 3.

Also, the metal pipe 32 can be assembled easily, if being wound fitting to the positions of the pump 1 and the heat-receiving jacket 2 in advance. Further, short-circuiting between the metal pipe 32 and the conductor on, such as a printed board, etc., can be escaped by applying an insulator coating upon the surface of the metal pipe 32.

For the organic material tube of the present embodiment, it also required that the permeation amount “q” of the connector tube for the coolant is equal to or less than the containing amount “Q” of the coolant, and for that purpose, the following materials are preferable, including, at least, the butyl rubber therein, and polysulfide rubber, fluororubber, hydrinrubber, ethylene-propylene rubber, as well.

FIG. 3 is a partial enlarged view for showing the connector tube 3, passing by between the main case 7 and the display case 8 of an electronic equipment or apparatus, according to a third embodiment of the present invention.

In FIG. 3, around the connector tube 3 is attached a protection tape 9 for use of protection against abrasion. With this protection tape 9, the lower the friction coefficient, the less the amount of friction or abrasion, therefore the effect thereof comes to be further high. The protection tape 9 may be attached in any direction, for example, in spiral or in ring-like, as far as being able to protect the portion where the main case 7 or the display case 8 is in contact with the connector tube 3, while maintaining the movability thereof. Also, since the protection tape 9 mentioned above can keep the connector tube in the condition of being curved in a shape, then it protects the connector tube 3 from buckling thereof. The connector tube 3 may be made of a material, such as butyl rubber, being less in the liquid permeability, as in the first embodiment mentioned above.

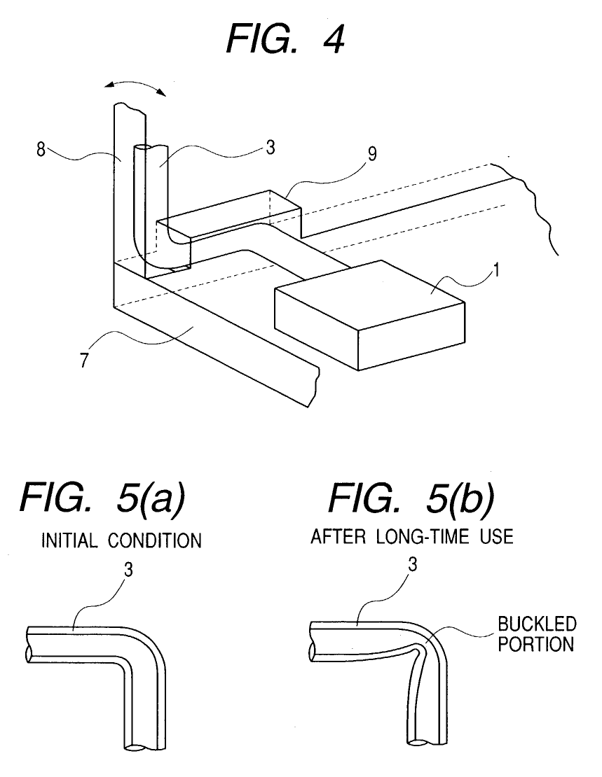

FIG. 4 is a perspective view for showing the details of the hinge portion between the main case and the display case, in the structure of the electronic equipment or apparatus, according to the embodiment mentioned above.

In FIG. 4, the display case 8 of the apparatus is opened and/or closed up to the maximum, i.e., 180 degree in angle, in every use thereof; therefore the connector tube 3 is in contact with either the main case 7 or the display case 8, and then it is worn down.

FIGS. 5(a) and 5(b) are partial enlarged views, for showing the conditions of the connector tube mentioned above, before the use and after a long-term use thereof.

As is shown in FIG. 5(a), the connector tube 3 shapes a splendid curve in an initial condition thereof, however if being used for a long time under the condition of a small curvature radius, as shown in FIG. 5(b), the connector tube 3 is buckled due to, so-called the creep phenomenon, thereby choking the flow passage, and therefore it is impossible to cool down the semiconductor element 5, fully, due to the reduce of flow amount therein.

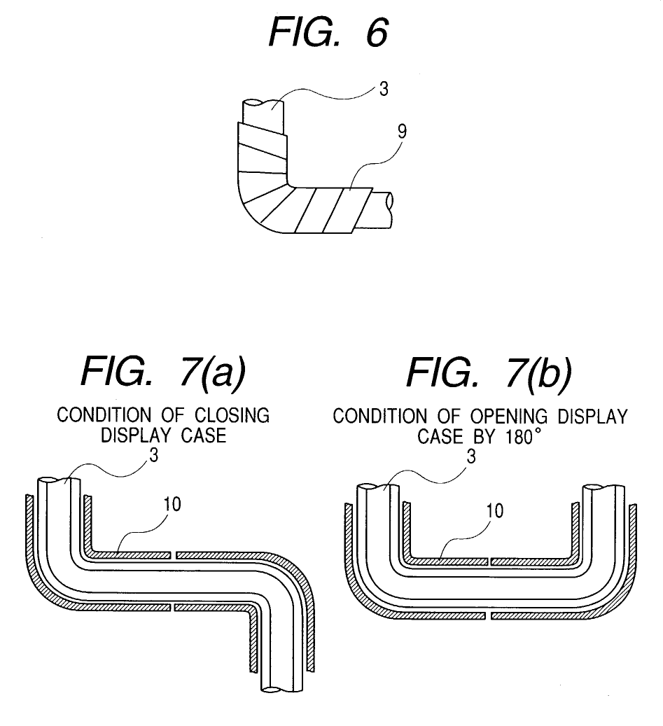

FIG. 6 is a view for showing the structure, in which the protection tube is attached on the tube, but in a portion other than the hinge portion between the main case and the display case, in the embodiment mentioned above.

In this FIG. 6, when the connector tube 3 is assembled or attached under the condition of being curved, in particular, among the pump 1, the tubes connecting between the pump 1, the heat-receiving jacket 2, the heat-radiation pipe and the tank 6, it is possible to maintain the shape of the connector tube in the curved condition thereof. For this reason, it is possible to protect the connector tuber from buckling thereof, thereby ensuring the cooling function of the semiconductor element for a long time.

However, as shown in FIG. 6, the protection tube is made up with two (2) parts thereof, and for that reason, even when the hinge portion is rotated by around 180 degree between the main case 7 and the display case 8, not the protection tube, but only the connector tube receives deformation due to the torsion, in the structure thereof.

FIGS. 7(a) and 7(b) are views for showing the conditions of the connector tube 3, passing by between the main case and the display case, in the electronic equipment or apparatus, according to a fourth embodiment of the present invention.

FIG. 7(a) shows the condition of the connector tube when the display case is closed, and the connector tube 3 is made of a material of small liquid permeability, such as butyl rubber, etc., as in the embodiment mentioned above. For the purpose of protecting the connector tube 3 from the abrasion and the buckling, a protection tube 10 is attached around the outer periphery of the connector tube 3, which has an inner diameter larger than the outer diameter of the connector tube. With this, in addition to the effect of protecting from the abrasion and the buckling, further there can be obtained an advantage that labor of attaching the tape can be abolished. Furthermore, forming the protection tube 10 in advance, under the condition of being curved along with the connector tube(s), brings about an advantage that no excessive load is applied upon the connector tube 3 due to the return of the protection tube 10. This protection tube 10, since the interior surface thereof is in contact with the connector tube 3 while the outer surface thereof with the main case 7 or the display case 8, therefore preferably, is made from a tube of a material of low friction coefficient, such as fluorocarbon polymer or resin.

FIG. 7(b) is for showing the condition of the connector tube when the display case is opened by 180 degree, and it brings about the same effect to that mentioned above by referring to FIG. 7(a).

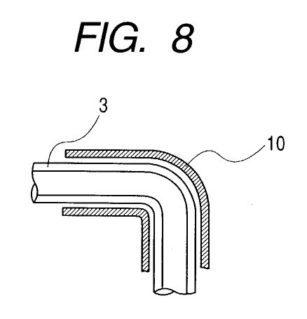

FIG. 8 is a partial enlarged view, for showing the condition that a protection tube is attached onto the tube in a portion other than the hinge portion between the main case and the display case, in the electronic equipment or apparatus, according to a fifth embodiment of the present invention.

In this FIG. 8, when the connector tube 3 is assembled under the condition of being curved, in particular, among those tubes connecting between the pump 1, the heat-receiving jacket 2, the heat-radiation pipe and the tank 6, it is possible to maintain the shape of the connector tube in the curved condition thereof. For this reason, it is possible to protect the connector tuber from buckling thereof, thereby ensuring the cooling function of the semiconductor element 5 for a long time.

According to this fifth embodiment of the present invention, the connector tube 3 is formed, fitting to the curved portions in accordance with a layout, including the pump 1, the heat-receiving jacket 2, the heat-radiation pipe 4 and the tank 6, in advance. For this reason, since no bending load is received thereupon, the connector tube will not be buckled down. This connector tube formed in advance may be applied to the connector tube 3 passing by between the main base and the display case.

### INDUSTRIAL APPLICABILITY

As was fully mentioned in the above, according to the present invention, there is provided an electronic equipment or apparatus, being able to reduce an amount of permeation of a coolant from the connection tubes, to prohibit the leakage of coolant due to abrasion of the flexible tube, and/or to prevent the flow amount from being decreased due to the buckle of the flexible tube, thereby enabling cooling of the semiconductor element with stability for a long time.

1. An electronic apparatus, comprising:
a case mounting a semiconductor element within an inside thereof;
a heat-receiving member being thermally connected with said semiconductor element;
a heat-radiation member being disposed on an interior surface side of said case;
a liquid driving means for driving a liquid coolant between said heat-radiation member and said heat-receiving member;
a tank for accumulating said liquid coolant therein; and
tubes for connecting between the tank, said heat-radiation member, and said heat-receiving member, wherein at least a part of said tube is made of butyl rubber.

2. An electronic apparatus, as described in the claim 1, wherein at least a part of said tube is formed of either one of nitrobutadien rubber, fluororubber, ethylene-propylene rubber, hydrinrubber, and polysulfide rubber.

3. An electronic apparatus, as described in the claim 1, wherein a penetration amount “q” of the coolant, which can be expressed by an equation blow, is determined to be equal to or less than a containing amount “Q” of the coolant:
q=2a.P.L.Δp.t/(In(r2/r1))
where “P” represents the rate of permeability of the coolant at the maximum temperature in use, “L” the total length of the tube, “Δp” the pressure difference between an inside and an outside of the tube (i.e., the vapor pressure difference) at the maximum temperature in use, “t” the longest time-period of use, “r1” the inner diameter of the tube, and “r2” the outer diameter of the tube, respectively.

4. An electronic apparatus, as described in the claim 1, wherein a protection tape is attached on a curved portion of said tube, for use of protection from abrasion and buckling.

5. An electronic apparatus, as described in the claim 1, wherein a protection tube is attached on an outer periphery of a curved portion of said tube, for use of protection from abrasion and buckling, and said protection tube has an inner diameter being larger than an outer diameter of said connection tube.

6. An electronic apparatus, as described in the claim 1, wherein said tube is formed, by winding itself in advance, fitting to a shape of a curved portion thereof.
